(19) United States
(12) Patent Application Publication
(10) Pub. No.: US 2014/0054785 A1
(43) Pub. Date: Feb. 27, 2014

(54) CHIP PACKAGE STRUCTURE AND METHOD FOR MANUFACTURING SAME

(71) Applicants: Zhen Ding Technology Co., Ltd., Tayuan (TW); HongQiSheng Precision Electronics (QinHuangDao) Co., Ltd., Qinhuangdao (CN)

(72) Inventor: FENG WANG, Qinhuangdao (CN)

(21) Appl. No.: 13/928,721

(22) Filed: Jun. 27, 2013

(30) Foreign Application Priority Data
Aug. 27, 2012 (CN) 2012103071635

(51) Int. Cl. H01L 23/488; H01L 21/50

(52) U.S. Cl. CPC H01L 23/488; H01L 21/50
USPC 257/773; 438/121

(57) ABSTRACT

A chip package structure includes a first wiring layer, a first solder mask layer, a chip and a plurality of third contact pads. The third contact pads are formed on the first wiring layer. The third contact pads and the first wiring layer are unitarily formed. The first solder mask layer is formed on the first wiring layer. The first solder mask layer defines a plurality of first openings to expose portions of the first wiring layers. The portions of the first wiring layers exposed to the first openings serve as first contact pads. The chip is mounted on the first solder mask layer and is electrically connected to the first contact pads. This disclosure further relates to a method of manufacturing the chip package structure.

### BACKGROUND

1. Technical Field

The present disclosure relates to a chip package structure and a method for manufacturing the same.

2. Description of Related Art

A chip package structure may include a circuit substrate and a chip. The circuit substrate is configured to form a connecting pad. Most of the circuit substrates include a plurality of wiring layers and a plurality of dielectric layers arranged each between adjacent wiring layers, which add to the thickness of the circuit substrate.

What is needed therefore is a chip package structure and a method for manufacturing the same to overcome the described limitations.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of a first copper foil, a carrier and a second copper foil in accordance with a first exemplary embodiment.

FIG. 2 shows the first copper foil, the carrier and the second copper foil of FIG. 1 laminated in that order.

FIG. 3 shows a photoresist layer formed on each of the first and second copper foils of FIG. 2.

FIG. 4 shows portions of the two photoresist layers in FIG. 3 removed to form two patterned photoresist layers.

FIG. 5 shows the first and second copper foils in FIG. 4 etched based on the two photoresist layers to form a first wiring layer and second wiring layer, etching depths being less than the thicknesses of the first and second copper foils, thus the first copper foil and the second copper foil not etched respectively serving as a first copper layer and a second copper layer.

FIG. 6 shows the patterned photoresist layers in FIG. 5 removed.

FIG. 7 shows a solder mask layer formed on each of the first and second wiring layers in FIG. 6.

FIG. 8 shows the solder mask layers each defining a plurality of openings to expose portions of the first and second wiring layers in FIG. 7, the portions of the first and second wiring layers serving as contact pads.

FIG. 9 shows surface treatment layers formed on the contact pads in FIG. 8.

FIG. 10 shows two package substrates with the carrier in FIG. 9 removed.

FIG. 11 shows a chip connected to one package substrate of FIG. 10.

FIG. 12 shows a molding compound applied to package the chip and the package substrate in FIG. 11 together.

FIG. 13 shows a patterned photoresist layer formed on the first copper layer of the package substrate in FIG. 12.

FIG. 14 shows the first copper layer in FIG. 13 etched to form third contact pads.

FIG. 15 shows a chip package with the patterned photoresist layer in FIG. 14 removed.

FIG. 16 is a cross-sectional view of a first copper foil, a first carrier, a second carrier and a second copper foil in accordance with a second exemplary embodiment.

FIG. 17 shows the first copper foil, the first carrier, the second carrier and the second copper foil of FIG. 16 laminated in that order.

FIG. 18 shows a photoresist layer formed on each of the first and second copper foils of FIG. 17.

FIG. 19 shows portions of the two photoresist layers in FIG. 18 removed to form two patterned photoresist layers.

FIG. 20 shows the first and second copper foils in FIG. 19 etched based on the two photoresist layers to form a first wiring layer and second wiring layer, etching depths being less than the thicknesses of the first and second copper foils, thus the first copper foil and the second copper foil not etched respectively serving as a first copper layer and a second copper layer.

FIG. 21 shows the patterned photoresist layers in FIG. 20 removed.

FIG. 22 shows a solder mask layer formed on each of the first and second wiring layers in FIG. 21.

FIG. 23 shows the solder mask layers each defining a plurality of openings to expose portions of the first and second wiring layers in FIG. 22, the portions of the first and second wiring layers serving as contact pads.

FIG. 24 shows surface treatment layers formed on the contact pads in FIG. 23.

FIG. 25 shows two package substrates with the first and second carriers in FIG. 24 separated from each other.

FIG. 26 shows a chip connected to one package substrate of FIG. 25.

FIG. 27 shows a molding compound applied to package the chip and the package substrate in FIG. 26 together.

FIG. 28 shows the first carrier in FIG. 28 removed.

FIG. 29 shows a patterned photoresist layer formed on the first copper layer of the package substrate in FIG. 28.

FIG. 30 shows the first copper layer in FIG. 29 etched to form third contact pads.

FIG. 31 shows a chip package with the patterned photoresist layer in FIG. 30 removed.

### DETAILED DESCRIPTION

Various embodiments will now be described in detail below with reference to the drawings.

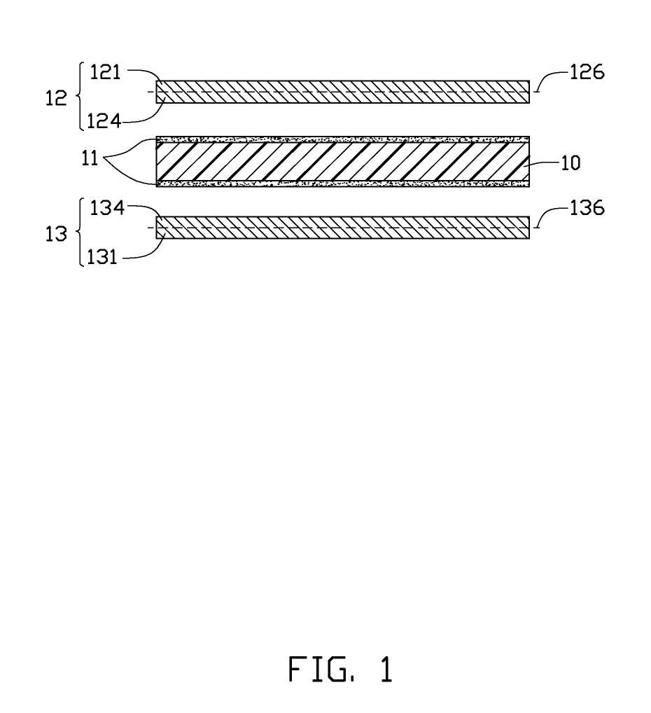

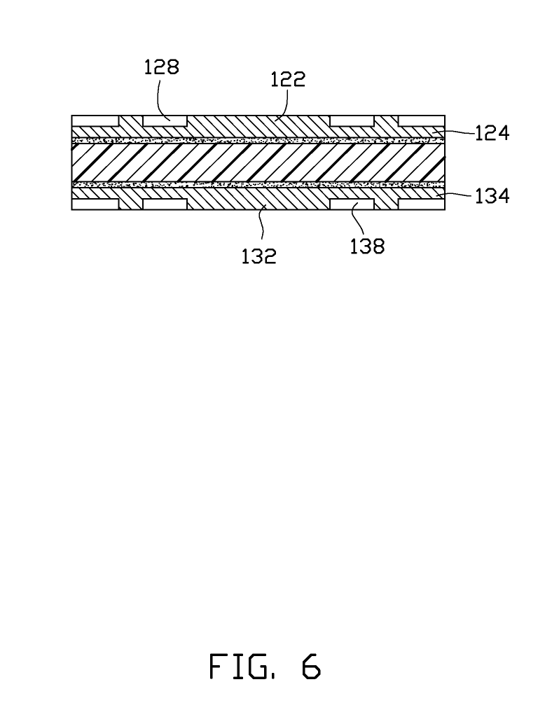

FIGS. 1-15 show a method for manufacturing a chip package in accordance with a first exemplary embodiment. The method includes the following steps.

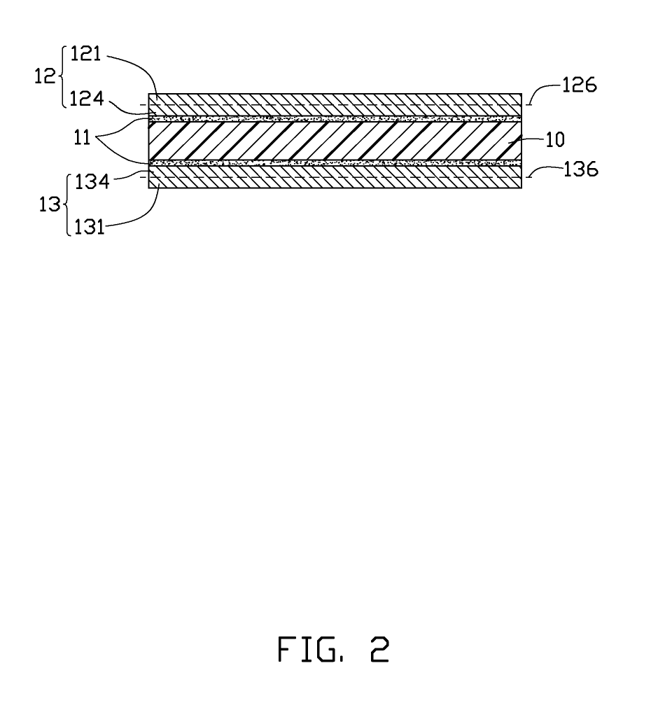

FIGS. 1 and 2 show that in step 1, provides a carrier 10 and two double-sided adhesive sheets 11 attached on two opposite sides of the carrier 10. Then, a first copper foil 12 is laminated on one of the adhesive sheets 11, and a second copper foil 13 is laminated on the other one of the adhesive sheets 11. The first copper foil 12 is a single body of material comprising an outer first copper layer 121 and an underlying second copper layer 124. The second copper foil 13 is single body of material comprising an outer third copper layer 131 and an underlying fourth copper layer 134. As shown in FIG. 1, the first copper layer 121 and the second copper layer 124 are partitioned by an imaginary line 126, and the third copper foil 131 and the fourth copper layer 134 are partitioned by an imaginary line 136. In this embodiment, the first copper layer 121 has an equal thickness to the second copper layer 124, and the third copper layer 131 has an equal thickness to the fourth copper layer 134.

The carrier 10 reinforces the rigidity of the first and second copper foils 12 and 13. In this embodiment, a material of the carrier 10 can be PI or a metal such as copper. The adhesive sheets 11 can be a release film made of PET.

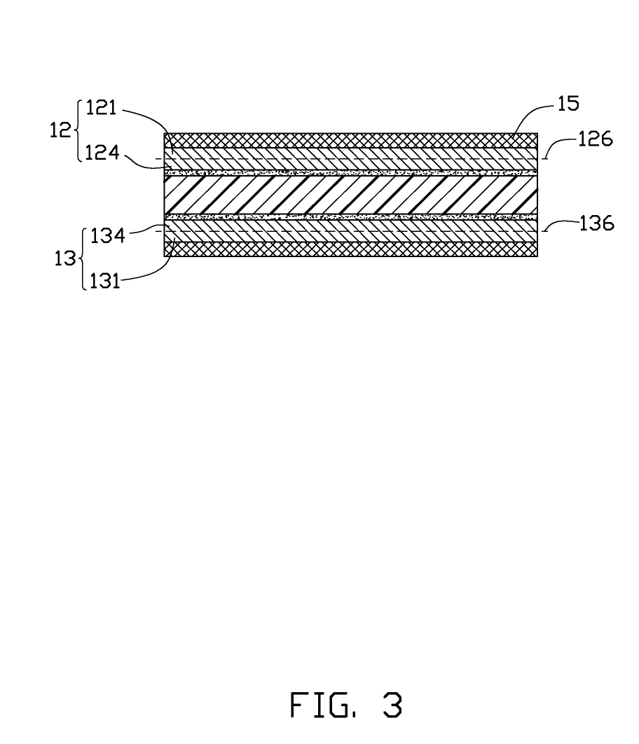

FIGS. 3-6 show that in step 2, the first copper layer 121 of the first copper foil 12 is selectively removed to form a first wiring layer 122 and second copper layer 124 first recesses 128, and the third copper layer 131 of the second copper foil 13 is selectively removed to form a second wiring layer 132 and fourth copper layer 134 second recesses 138.

A method for forming the first wiring layer 122 second copper layer 124 is described as follows:

First, FIG. 3 shows that a photoresist layer 15 is laminated on a surface of the first copper layer 121. In this embodiment, the photoresist layer 15 is a dry-film type.

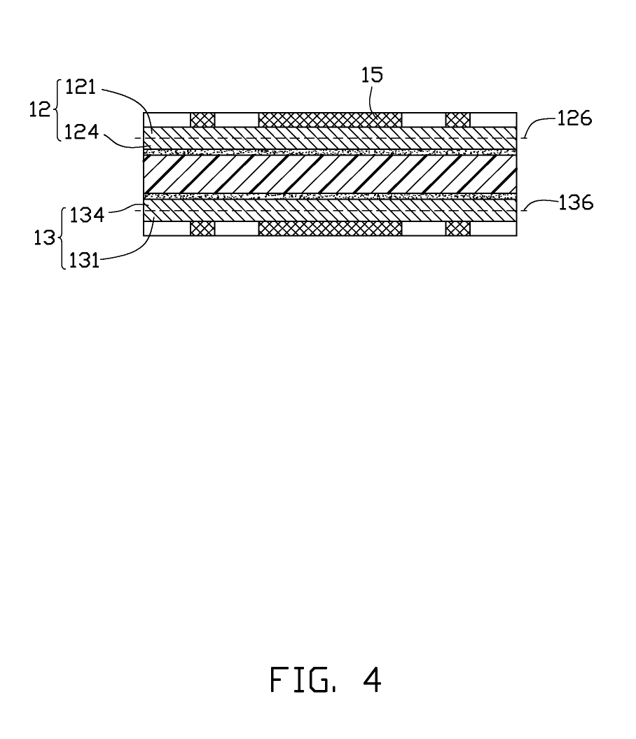

Second, FIG. 4 shows that the photoresist layer 15 is selectively exposed and is developed to form a patterned photoresist layer 15. Portions of the first copper layer 121 are exposed through the patterned photoresist layer 15.

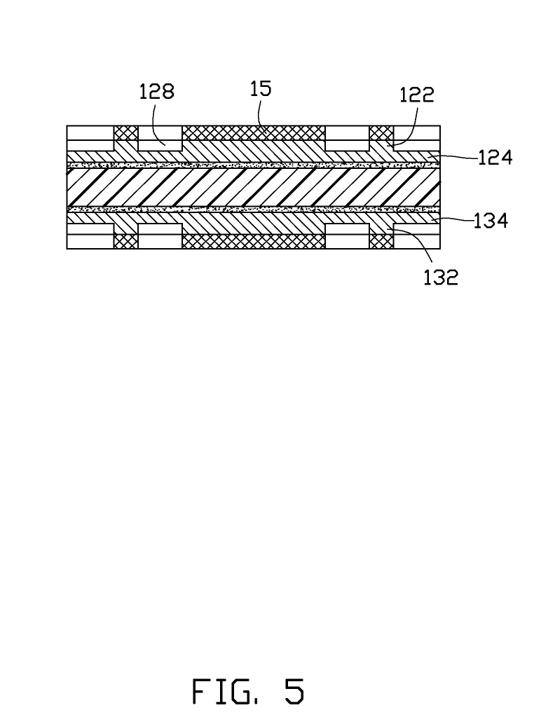

Third, FIG. 5 shows that the first copper layer 121 is etched based on the patterned photoresist layer 15, thereby forming the first wiring layer 122 and patterned, first recesses 128 in the surface of the first copper layer 121 adjacent to the photoresist layer 15. The second copper layer 124 is exposed at the first recesses 128. That is to say, a depth of the first recesses 128 is equal to the thickness of the first copper layer 121. Thus, the first wiring layer 122 is adjacent to the patterned photoresist layer 15, and has half the thickness of first copper foil 12. Thus, the second copper layer 124 is adjacent to the respective adhesive sheet 11. Finally, the first photoresist layer 15 is removed.

The second wiring layer 132 is formed by selectively removing the second copper foil 13. The etching method is similar as that for forming the first wiring layer 122. Second recesses 138 corresponding to the first recesses 128 are defined between the second wiring layer 132.

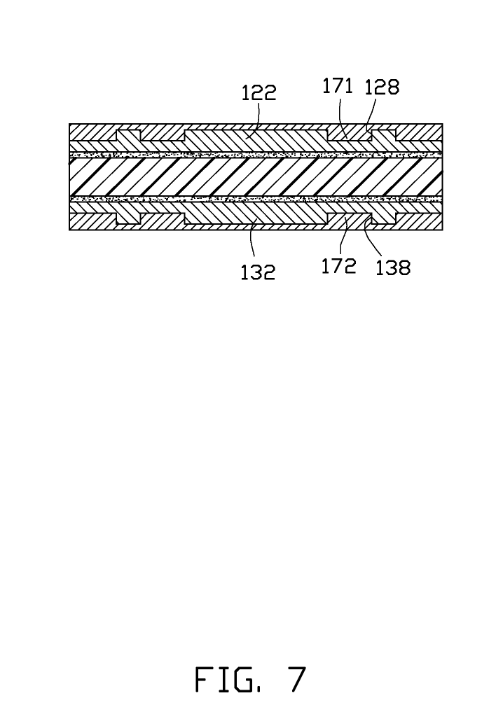

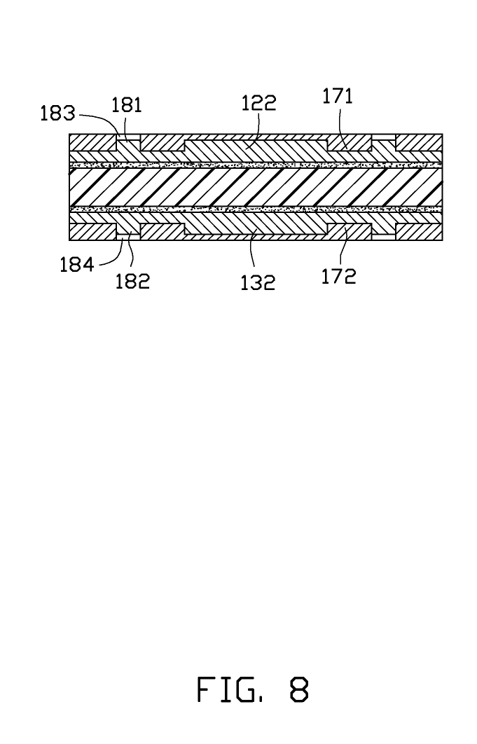

FIGS. 7-8, in step 3, show a first solder mask layer 171 is formed on the first wiring layer 122, and a second solder mask layer 172 is formed on the second wiring layer 132. The first solder mask layer 171 defines a plurality of first openings 183 to expose portions of the first wiring layers 122. The second solder mask layer 172 defines a plurality of second openings 184 to expose portions of the second wiring layers 132. The portions of the first wiring layers 122 exposed at the first openings 183 serve as first contact pads 181. The portions of the second wiring layers 132 exposed at the second openings 184 serve as second contact pads 182.

In this embodiment, a method for forming the first solder mask layer 171 is described as follows. First, FIG. 7 shows that a liquid photoimageable solder resist ink is coated on the first wiring layer 122 and filled in the first recesses 124, and is procured. Second, FIG. 8 shows that the photoimageable solder resist ink are selectively exposed and are developed by a UV light, thereby forming the first openings 183 and exposing the first contact pads 181. Finally, the photoimageable solder resist ink is post-cured to form the first solder mask layer 171. The second solder mask layer 172 is formed by a method similar to that for forming the first solder mask layer 171. In an alternative embodiment, the first and second solder mask layers 171 and 172 can also be formed by a screen printing method. In the screen printing method, the exposing process and the development process are omitted.

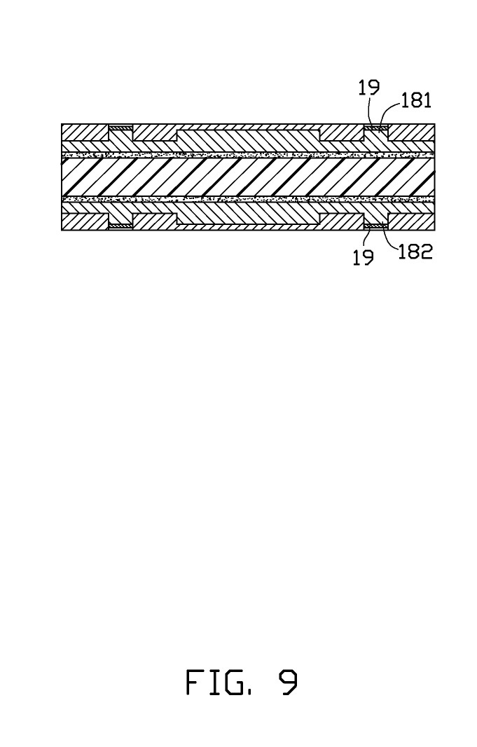

FIG. 9, in step 4, a surface plating layer 19 is formed on each of the first contact pads 181 and each of the second contact pads 182.

The surface plating layer 19 can be formed by plating gold, plating nickel-gold, plating nickel-palladium-gold or tin. The surface plating layer 19 prevents the first and second contacts 181 and 182 from oxidation, and is beneficial for the connection to gold wires of a chip in a later step.

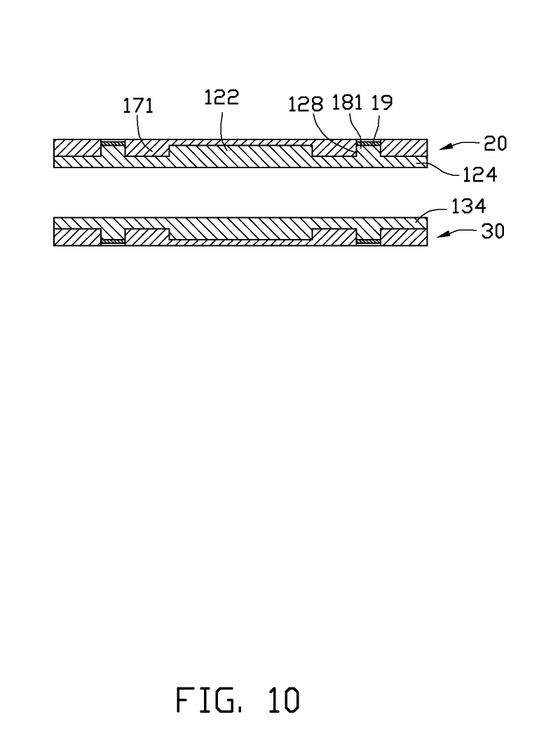

FIG. 10, in step 5, the first and second copper layers 124 and 134 are separated from the carrier 10 by peeling the adhesive sheets 11. Thus, a first package substrate 20 and a second package substrate 30 are obtained. The first package substrate 20 and the second package substrate 30 are easily separated from the carrier 10 because the adhesive sheets 11 is easily peeled off from the first and second copper layers 124 and 134.

FIG. 10 shows that the first package substrate 20 is identical to the second package substrate 30, thus, only the first package substrate 20 is described as follows. The first package substrate 20 includes a second copper layer 124, a first wiring layer 122 and a first solder mask layer 171. The first wiring layer 122 is integrally formed with the second copper layer 124. That is, the second copper layer 124 and the first wiring layer 122 are unitarily formed. First recesses 128 are defined between the conductive wires of the first wiring layer 122. The first solder mask layer 171 is formed on the first wiring layer 122 and is filled in the first recesses 128. The first solder mask layer 171 defines a plurality of first openings 183 exposing portions of the first wiring layers 122. The portions of the first wiring layers 122, which are exposed at the first openings 183, serve as first contact pads 181. A surface plating layer 19 is formed on each of the first contact pads 181.

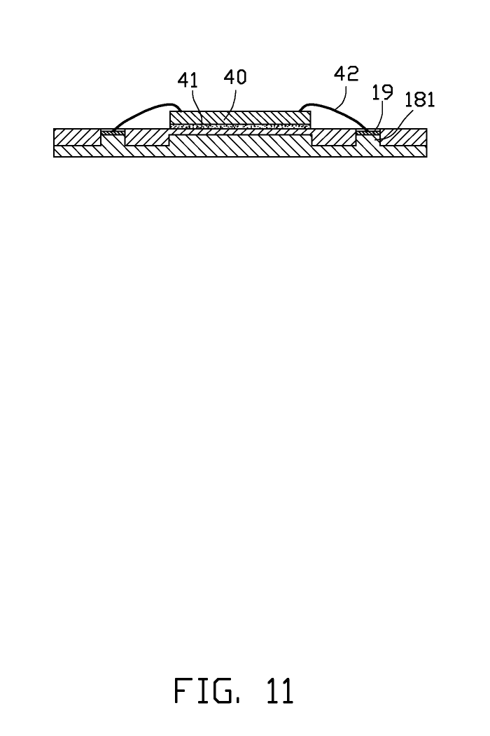

FIG. 11 shows that in step 6, a chip 40 is positioned on the first package substrate 20 and is electrically connected to the first package substrate 20.

In detail, the chip 40 includes a plurality of electrodes (not shown) and a plurality of bonding wires 42 respectively in connection with the electrodes. A terminal portion of the bonding wires 42 is welded to the surface plating layers 19 on the first contact pads 181, thereby electrically connecting the chip 40 to the first wiring layer 122 of the first package substrate 20. In this embodiment, the chip 40 is fixed on the first solder mask layer 171 through an adhesive layer 41. The bonding wires 42 can be gold.

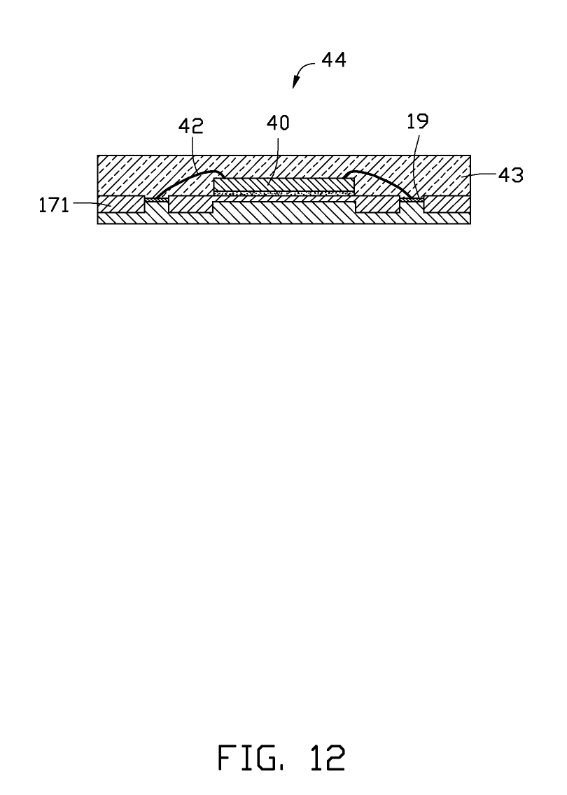

FIG. 12 shows that in step 7, a molding compound layer 43 is applied on the chip 40 and the package substrate 20 to entirely cover the bonding wires 42, the chip 40, an exposed portion of the first solder mask layer 171 and the surface plating layers 19 on the first contact pads 181, thereby forming a package body 44. In this embodiment, the molding compound layer 43 can be thermosetting resin, for example, polyimide resin, epoxy resin, or silicone resin, for example.

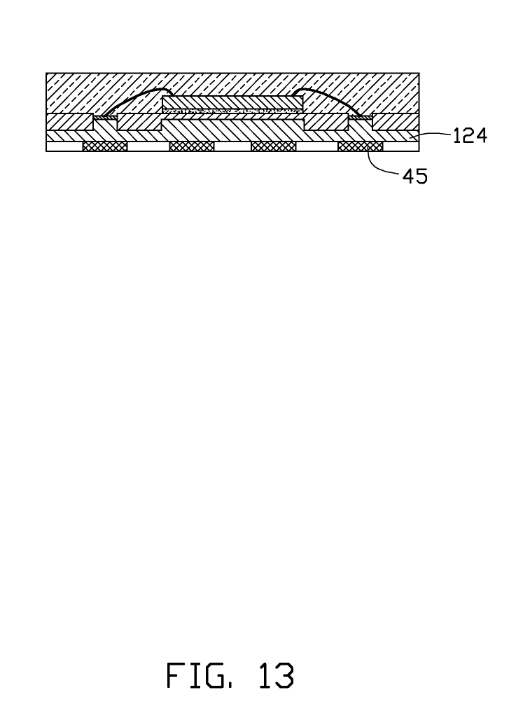

FIGS. 13-15 shows that in step 8, the second copper layer 124 is selectively removed to form a plurality of third contact pads 125. Thus, a chip package structure 50 is obtained.

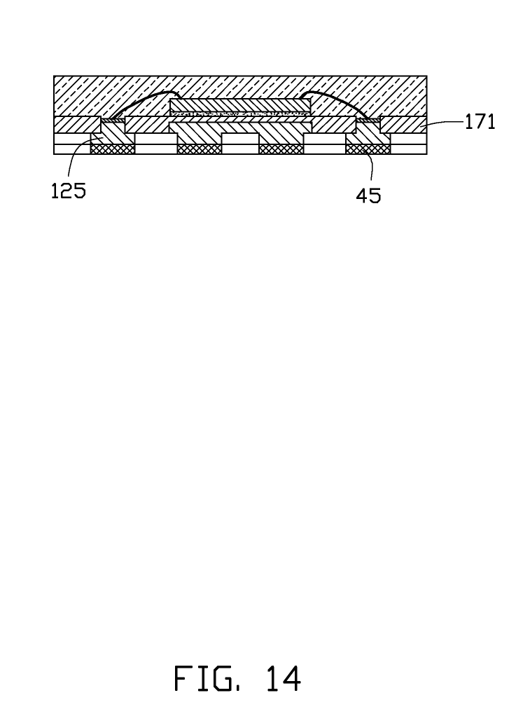

The third contact pads 125 are formed by a method described as follows. First, FIG. 13 shows that a photoresist layer 45 is formed on the second copper layer 124. In this embodiment, the photoresist layer 45 can be a dry-film type. Second, as shown in FIG. 14, the photoresist layer 45 is selectively exposed and developed to form a patterned photoresist layer 45. Portions of the second copper layer 124 are exposed through the patterned photoresist layer 45. Third, the second copper layer 124 is etched in based on the patterned photoresist layer 45, thereby obtaining the third contact pads 125. The etching depth is equal to the thickness of the second copper layer 124, thereby exposing the first solder mask layer 171. Thus, the first wiring layer 122 is not etched. Finally, the patterned photoresist layer 45 is removed, thereby obtaining the chip package structure 50.

In an alternative embodiment, the chip 40 can also be packaged on the first package substrate 20 through a flip-chip mounting method.

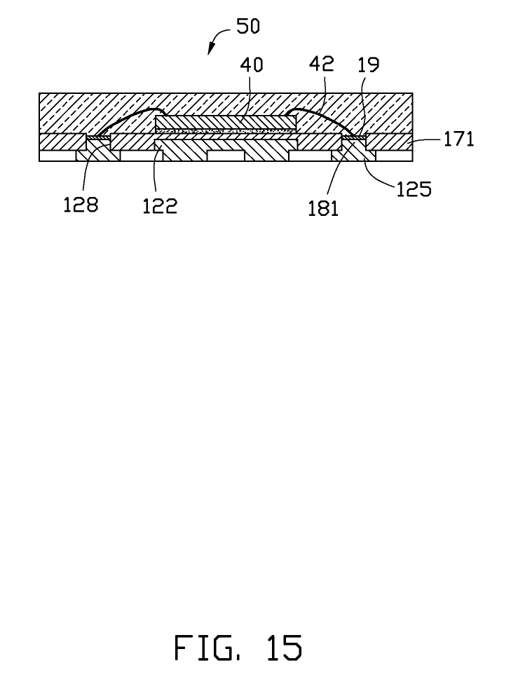

FIG. 15 shows that the chip package structure 50 in this embodiment includes a first wiring layer 122, a first solder mask layer 171, a chip 40, a molding compound layer 43 and a third contact pads 125. The first solder mask layer 171 is formed on the surface of the first wiring layer 122 and is filled in the recesses 128 between the conductive wires of the first wiring layer 122. The first solder mask layer 171 defines a plurality of first openings 183 exposing portions of the first wiring layers 122. The portions of the first wiring layers 122 exposed at the first openings 183 serve as first contact pads 181. A surface plating layer 19 is formed on each of the first contact pads 181. The chip 40 includes a plurality of electrodes (not shown) and a plurality of bonding wires 42 respectively in connection with the electrodes. A terminal portion of the bonding wires 42 is welded to the surface plating layers 19 on the first contact pads 181, thereby electrically connects the chip 40 to the first wiring layer 122 of the first package substrate 20. The molding compound layer 43 is applied on the chip 40 and the package substrate 20 to entirely cover the bonding wires 42, the chip 40, an exposed portion of the first solder mask layer 171, and the surface plating layers 19 on the first contact pads 181. The third contact pads 125 is formed on a surface of the first wiring layer 122 facing away from the first solder mask layer 171. The third contact pads 125 and the first wiring layer 122 unitarily formed. The third contact pads 125 are connected to a printed circuit board or another package substrate. Solder balls can be formed on the third contact pads 125.

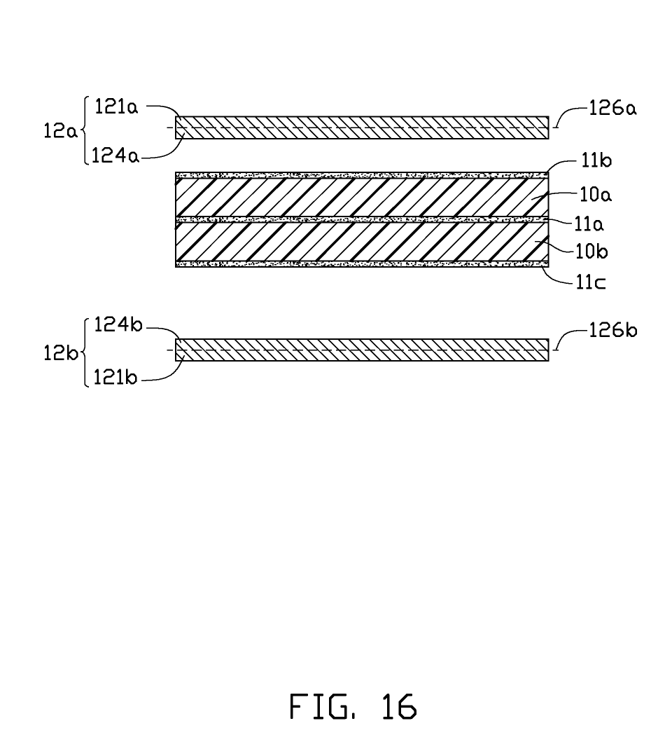

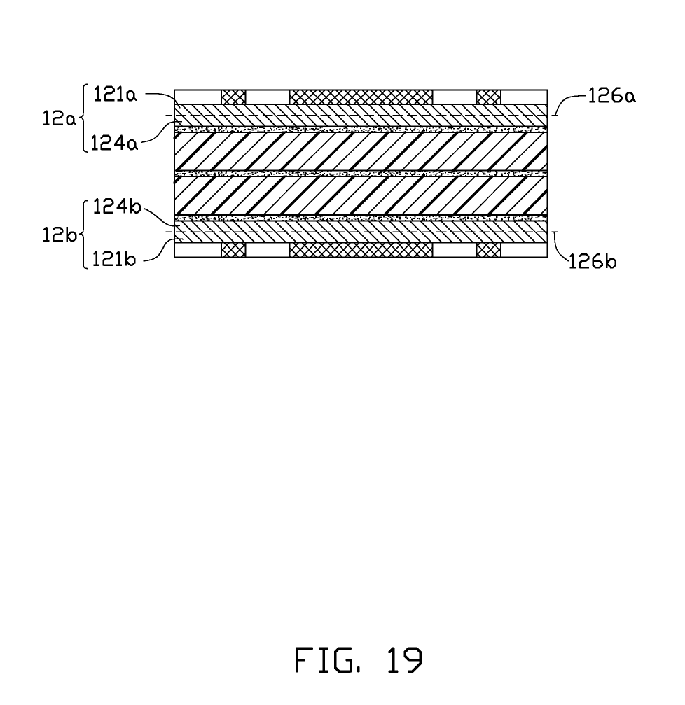

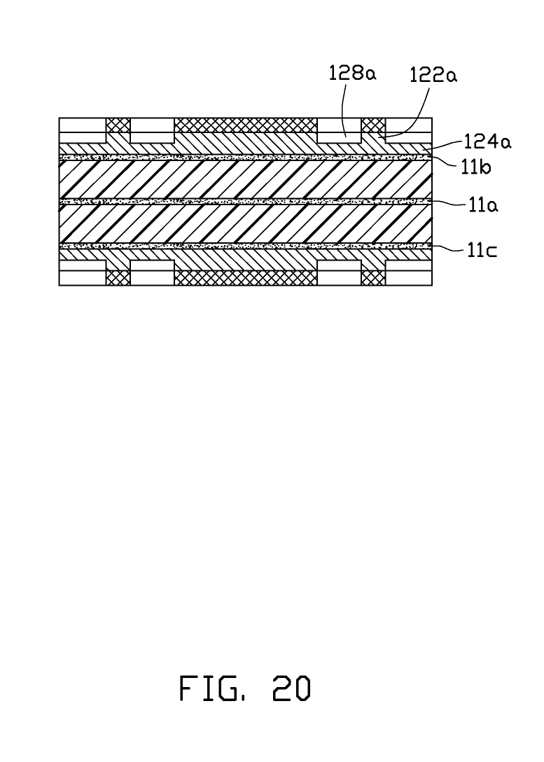

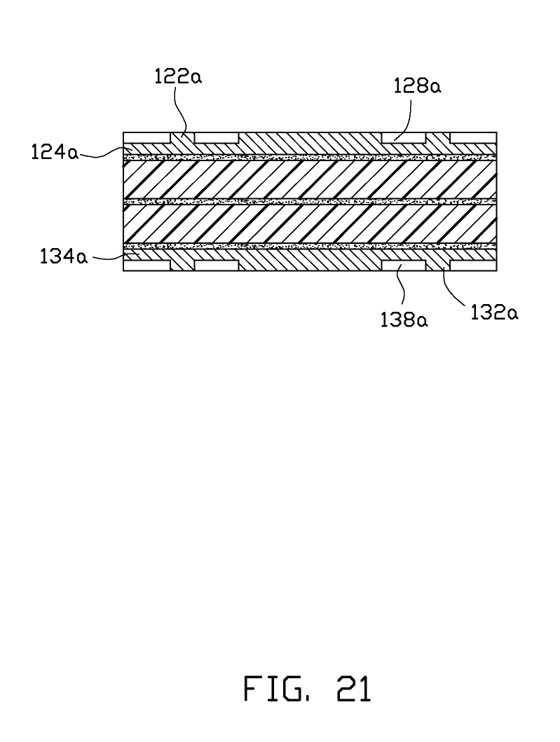

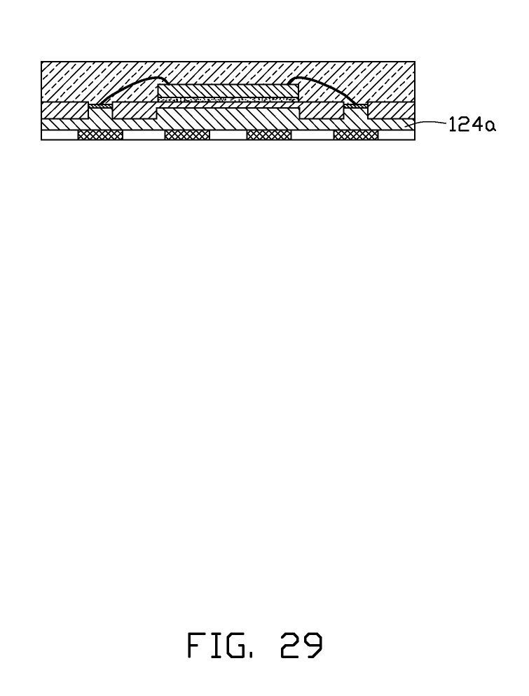

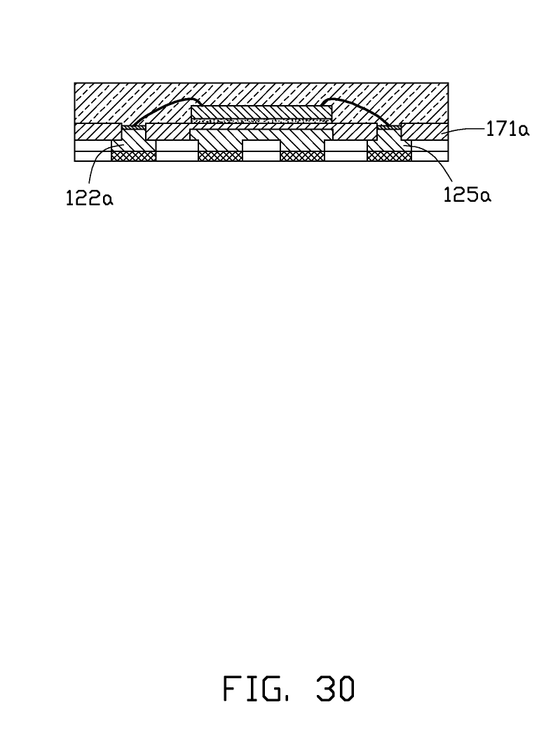

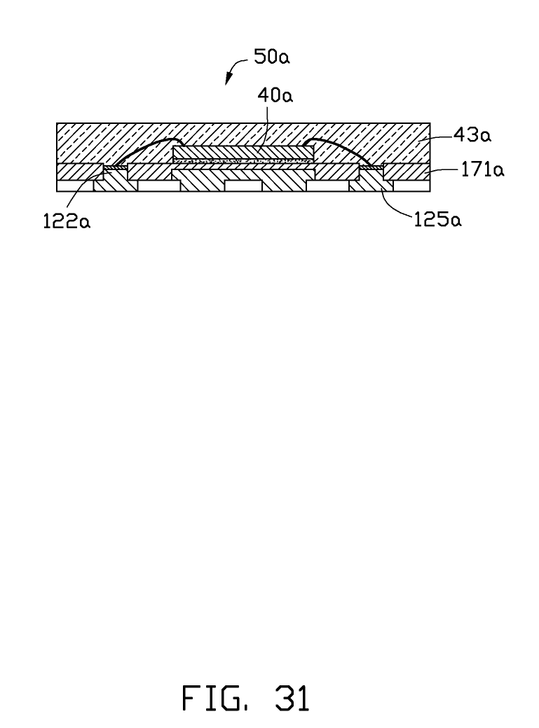

FIGS. 16-31 show a method for manufacturing a chip package in accordance with a second exemplary embodiment. The method includes the following steps.

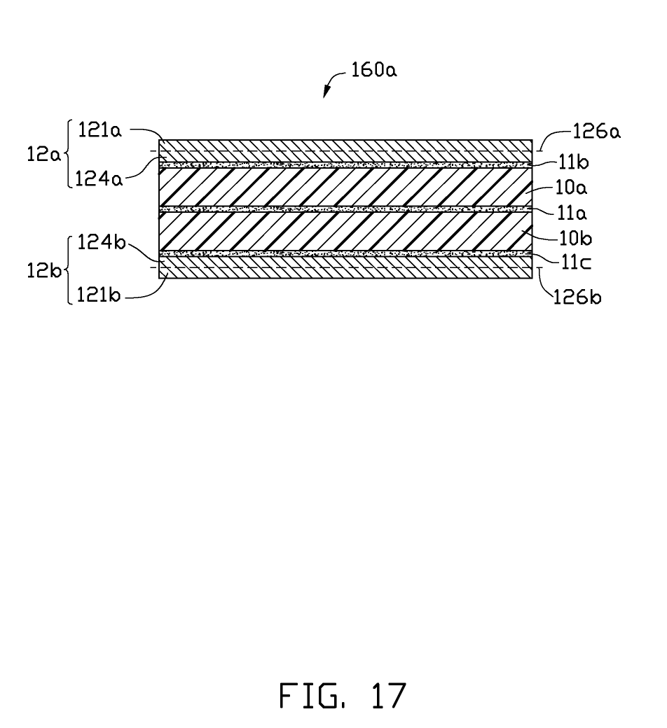

FIGS. 16 and 17 show that in step (1), a first carrier 10a, a second carrier 10b, a first double-sided adhesive sheet 11a, a second double-sided adhesive sheet 11b, and a third double-sided adhesive sheet 11c are provided. The first carrier 10a and the second carrier 10b are attached on opposite surfaces of the first adhesive sheet 11a. The second adhesive sheet 11b is attached on a surface of the first carrier 10a facing away from the first adhesive sheet 11a. The third adhesive film 11c is attached on a surface of the second carrier 10b facing away from the first adhesive sheet 11a. Then a first copper foil 12a is laminated on the second adhesive sheet 11b, and a second copper foil 13a is laminated on the third adhesive sheet 11c. The first copper foil 12a is a single body of material comprising an outer first copper layer 121a and an underlying second copper layer 124a. The second copper foil 13a is single body of material comprising an outer third copper layer 131a and an underlying fourth copper layer 134a. As shown in FIG. 1, the first copper layer 121a and the second copper layer 124a are partitioned by an imaginary line 126a, and the third copper foil 131a and the fourth copper layer 134a are partitioned by an imaginary line 136a. In this embodiment, the first copper layer 121a has an equal thickness to the second copper layer 124a, and the third copper layer 131a has an equal thickness to the fourth copper layer 134a.

The first and second carriers 10a and 10b reinforce the rigidity of the first and second copper foils 12a and 13a. In this embodiment, a material of the first and second carriers 10a and 10b can be PI or a metal such as copper. The first, second and third adhesive sheets 11a, 11b and 11c each can be a release film made of PET.

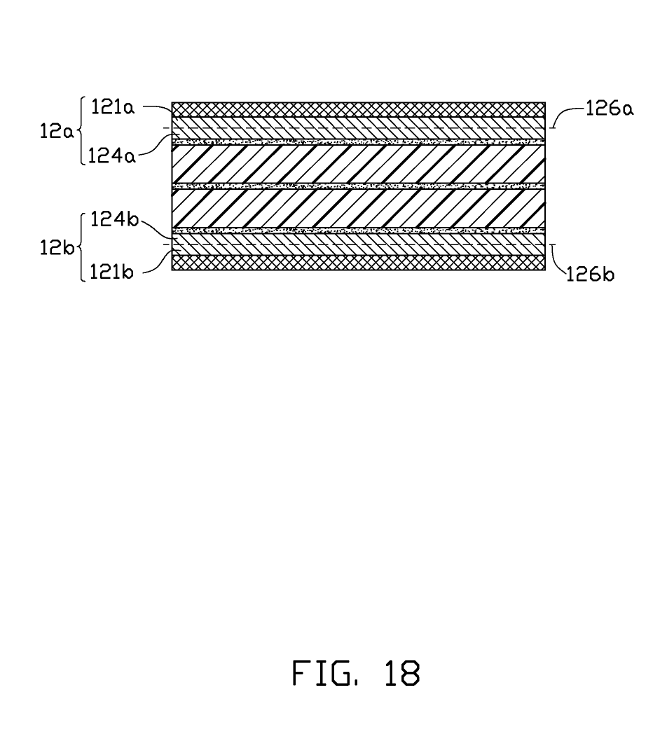

FIGS. 18-21 show that in step (2), the first copper layer 121a of the first copper foil 12a is selectively removed to form a first wiring layer 122a and a second copper layer 124 first recesses 128a, and the third copper layer 131a of the second copper foil 13a is selectively removed to form a second wiring layer 132a and a fourth copper layer 134a second recesses 138a.

A method for forming the first wiring layer 122a and a method for forming the second wiring layer 132a can be similar as the method for forming the first wiring layer 122 as described in the first exemplary embodiment. First recesses 128a corresponding to the first recesses 128 are defined between the first wiring layer 122a, and second recesses 138a corresponding to the second recesses 138 are defined between the second wiring layer 132a.

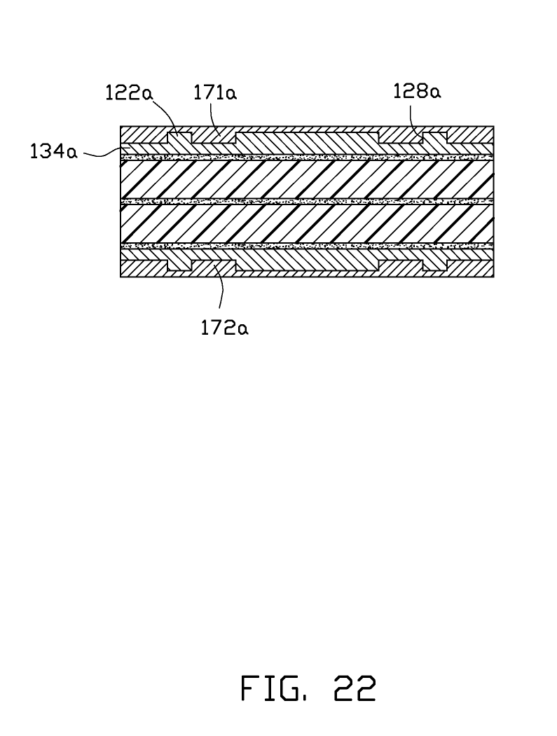

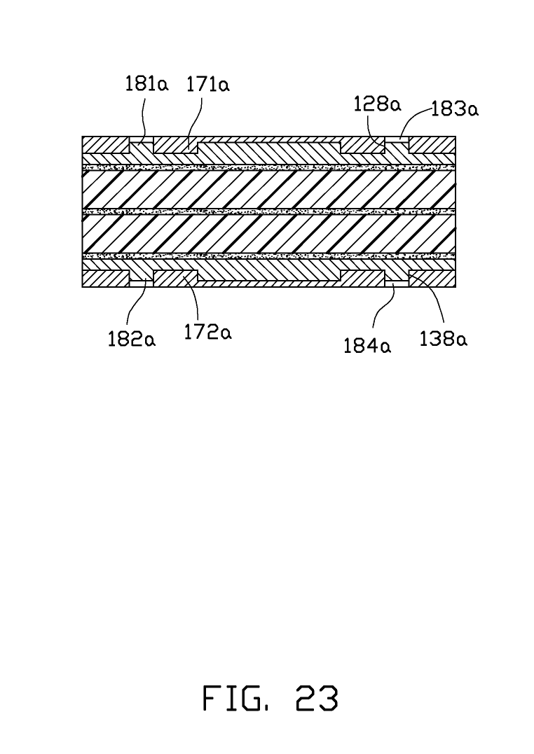

FIGS. 22 and 23 shows that in step (3), a first solder mask layer 171a is formed on the first wiring layer 122a, and a second solder mask layer 172a is formed on the second wiring layer 132a. The first solder mask layer 171a defines a plurality of first openings 183a to expose portions of the first wiring layers 122a. The second mask layer 172a defines a plurality of second openings 184a to expose portions of the second wiring layers 132a. The portions of the first wiring layers 122a exposed at the first openings 183a serve as first contact pads 181a. The portions of the second wiring layers 132a exposed at the second openings 184a serve as second contact pads 182a.

Methods for forming the first solder mask layer 171a and the second solder mask layer 172a can be similar as the method for forming the first solder mask layer 171 as described in the first exemplary embodiment.

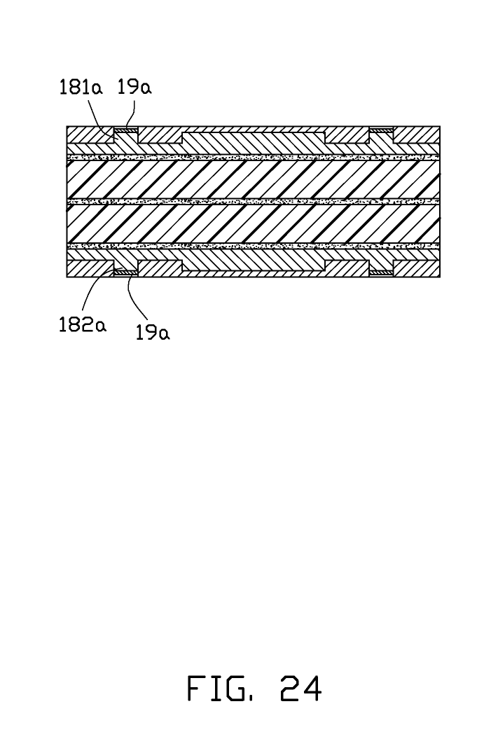

FIG. 24 show that in step (4), a surface plating layer 19a is formed on each of the first contact pads 181a and each of the second contact pads 182a. A method for forming the surface plating layer 19a can be similar as the method for forming the surface plating layer 19 as described in the first exemplary embodiment.

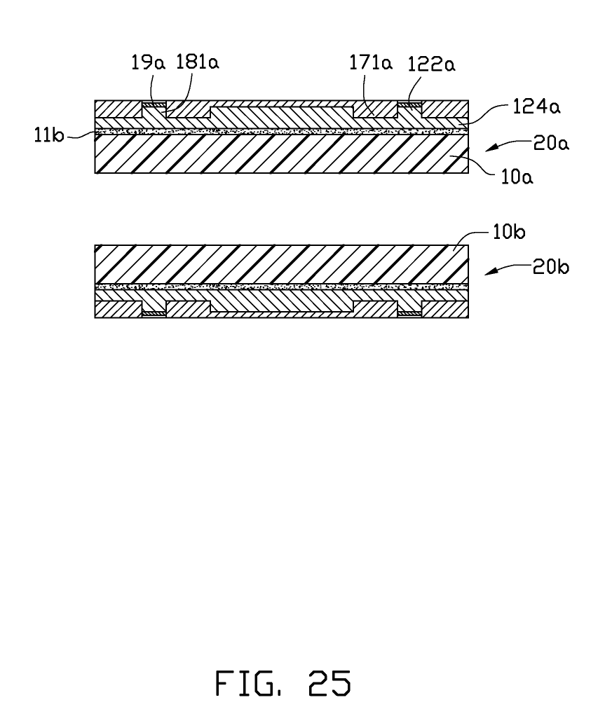

FIG. 25 shows that in step (5), the first carrier 10a and the second carrier 10b are separated from each other by peeling the first adhesive sheet 11a. Thus, a first package substrate 20a and a second package substrate 30a are obtained. The first package substrate 20a and the second package substrate 30a are easily separated from each other because the first adhesive sheet 11a is easily peeled off from the first and second carries 10a and 10b.

FIG. 25 shows that the first package substrate 20a and is identical to the second package substrate 30a. Thus, only the first package substrate 20a is described as follows. The first package substrate 10a is similar as the first package substrate 20 in the first exemplary embodiment and the differences are the first package substrate 20a further includes the second adhesive sheet 11b and the first carrier 10a. The second adhesive sheet 11b is attached on the second copper layer 124a, and the first carrier 10a is attached on the second adhesive sheet 11b.

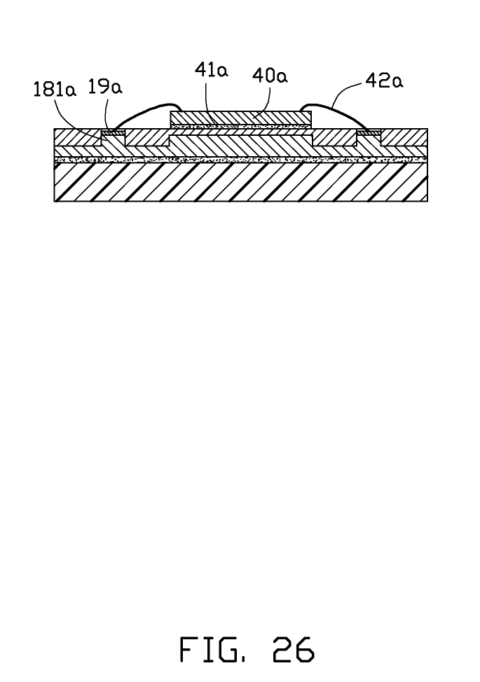

FIG. 26 shows that in step (6), a chip 40a is positioned on the first package substrate 20a and is electrically connected to the first package substrate 20a.

In detail, the chip 40a includes a plurality of electrodes (not shown) and a plurality of bonding wires 42a respectively in connection with the electrodes. A terminal portion of the bonding wires 42a is welded to the surface plating layers 19a on the first contact pads 181a, thereby electrically connecting the chip 40a to the first wiring layer 122a of the first package substrate 20a. In this embodiment, the chip 40a is fixed on the first solder mask layer 171a through an adhesive layer 41a. The bonding wires 42a can be comprised of gold.

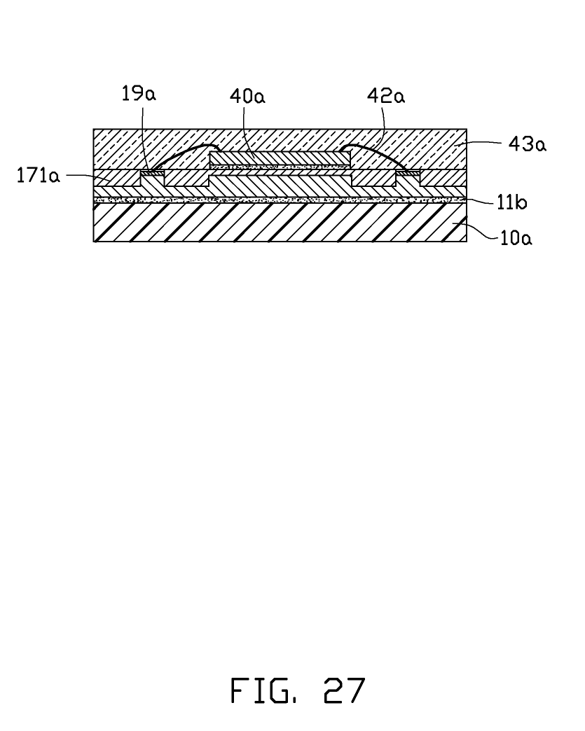

FIG. 27 shows that in step (7), a molding compound layer 43a is applied on the chip 40a and the package substrate 20a to entirely cover the bonding wires 42a, the chip 40a, an exposed portion of the first solder mask layer 171a and the surface plating layers 19a on the first contact pads 181a. In this embodiment, the molding compound layer 43a can be thermosetting resin, for example, polyimide resin, epoxy resin, or silicone resin, for example.

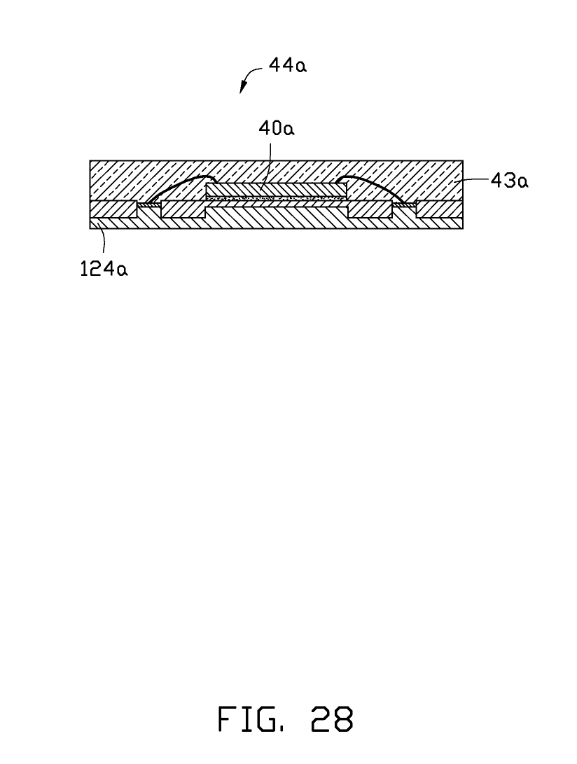

FIG. 28 shows that the first carrier 10a is separated from the second copper layer 124a, thereby forming a package body 44a. The first carrier 10a is easily separated from the second copper layer 124a because the second adhesive sheet 11b is easily peeled off from the second copper layer 124a.

FIGS. 28-31 show that in step 8, the first copper layer 124a is selectively removed to form a plurality of third contact pads 125a. Thus, a chip package structure 50a is obtained. A method for forming the third contact pads 125a is similar as the method for forming the third contact pads 125 as described in the first exemplary embodiment.

In an alternative embodiment, the chip 40a can also be packaged on the first package substrate 20a through a flip-chip mounting method.

In the first and second embodiments, there is no dielectric layer between the first wiring layer and the third contact pads, thereby obtaining a thinner chip package structure.

While certain embodiments have been described and exemplified above, various other embodiments from the foregoing disclosure will be apparent to those skilled in the art. The present disclosure is not limited to the particular embodiments described and exemplified, but is capable of considerable variation and modification without departure from the scope and spirit of the appended claims.

1. A method for manufacturing a chip package structure, comprising:
providing a carrier and a first copper foil, the first copper foil and the carrier attached on opposite sides of a double-sided adhesive sheet, the first copper foil comprising an outer first copper layer and an underlying second copper layer;
selectively removing portions of the first copper layer thereby forming a first wiring layer and a plurality of first recesses in the first wiring layer with corresponding underlying portions of the second copper layer being exposed therefrom;
forming a first solder mask layer on the first wiring layer and in the first recesses, and defining a plurality of first openings in the first solder mask layer to expose portions of the first wiring layers, the portions of the first wiring layers exposed at the first openings serving as first contact pads;
removing the carrier and the adhesive sheet;
mounting a chip on the first solder mask layer, and electrically connected the chip to the first contact pads; and
selectively removing portions of the second copper layer to form a plurality of third contact pads, thereby obtaining a chip package structure.

2. The method of claim 1, further comprising providing another double-sided adhesive sheet and a second copper foil, the second copper foil attached on an opposite side of the carrier using said another double-sided adhesive sheet, the second copper foil comprising an outer third copper layer and an underlying fourth copper layer; selectively removing portions of the outer third copper layer of the second copper foil, thereby forming a second wiring layer and a plurality of second recesses in the second wiring layer, to expose corresponding underlying portions of the fourth copper layer; further forming a second solder mask layer on the second wiring layer and in the second recesses, and defining a plurality of second openings in the second solder mask layer to expose portions of the second wiring layer, the portions of the second wiring layer exposed at the second openings serving as second contact pads; and removing said another adhesive sheet to separate the second and fourth copper layers from each other.

3. The method of claim 1, wherein the chip comprises a plurality of electrodes and a plurality of bonding wires electrically connected to the electrodes, the step of mounting a chip on the first solder mask layer comprising:
connecting terminal portions of the bonding wires to the first contact pads; and
applying a molding compound layer to entirely cover the bonding wires, the chip, exposed portions of the first solder mask layer and the first contact pads.

4. The method of claim 1, wherein the step of selectively removing portions of the first copper layer comprises:
forming a patterned photoresist layer on a surface of the first copper layer of the first copper foil, with portions of the first copper layer exposed through the patterned photoresist layer; and
removing portions of the first copper layer exposed through the patterned photoresist layer to expose the underlying portions of the second copper layer.

5. The method of claim 4, wherein the thickness of the first copper layer is equal to the thickness of the second copper layer.

6. The method of claim 1, wherein for the step of selectively removing portions of the second copper layer to form a plurality of third contact pads comprises:
forming a patterned photoresist layer on a surface of the second copper layer facing away from the first solder mask layer, with portions of the second copper layer exposed through the patterned photoresist layer; and
removing the portions of the second copper layer exposed through the patterned photoresist layer, thereby obtaining the third contact pads.

7. A method for manufacturing a chip package structure, comprising:
providing a first carrier, a second carrier, a first copper foil and a second copper foil, the first and second carrier attached on opposite sides of a doubled-sided first adhesive sheet, the first copper foil attached on a side of the first carrier facing away from the second carrier through a double-sided second adhesive sheet, the second copper foil attached on a side of the second carrier facing away from the first carrier through a double-sided third adhesive sheet, the first copper foil comprising an outer first copper layer and an underlying second copper layer, the second copper foil comprising an outer third copper layer and an underlying fourth copper layer;
selectively removing portions of the first copper layer, thereby forming a first wiring layer and a plurality of first recesses in the first wiring layer with corresponding underlying portions of the second copper layer exposed therefrom;
selectively removing portions of the third copper layer, thereby forming a second wiring layer and a plurality of second recesses in the second wiring layer with corresponding underlying portions of the fourth copper layer exposed therefrom;
forming a first solder mask layer on the first wiring layer and in the first recesses, and defining a plurality of first openings in the first solder mask layer to expose portions of the first wiring layers, the portions of the first wiring layers exposed at the first openings serving as first contact pads;
forming a second solder mask layer on the second wiring layer and in the second recesses, and defining a plurality of second openings in the second solder mask layer to expose portions of the second wiring layers, the portions of the second wiring layers exposed at the second openings serving as second contact pads;
separating the first and second carrier and removing the first adhesive sheet;
mounting a chip on the first solder mask layer, and electrically connected the chip to the first contact pads;
removing the first carrier; and
selectively removing portions of the second copper layer to form a plurality of third contact pads, thereby obtaining a chip package structure.

8. The method of claim 7, wherein the chip comprises a plurality of electrodes and a plurality of bonding wires electrically connected to the electrodes, the step of mounting a chip on the first solder mask layer comprising:
connecting terminal portions of the bonding wires to the first contact pads; and
applying a molding compound layer to entirely cover the bonding wires, the chip, exposed portions of the first solder mask layer and the first contact pads.

9. The method of claim 7, the step of selectively removing portions of the first copper layer comprises:
forming a patterned photoresist layer on a surface of the first copper layer of the first copper foil, with portions of the first copper layer exposed through the patterned photoresist layer; and
removing portions of the first copper layer exposed through the patterned photoresist layer to expose the second copper layer.

10. The method of claim 9, wherein the thickness of the first copper layer is equal to the thickness of the second copper layer.

11. The method of claim 7, wherein for the step of selectively removing portions the first second copper layer to form a plurality of third contact pads comprises:
forming a patterned photoresist layer on a surface of the second copper layer facing away from the first solder mask layer, portions of the second copper layer exposed to the patterned photoresist layer; and
removing portions of the second copper layer exposed to the patterned photoresist layer, thereby obtaining the third contact pads.

12. A chip package structure, comprising a first wiring layer, a first solder mask layer, a chip and a plurality of third contact pads, the third contact pads formed on the first wiring layer, the third contact pads and the first wiring layer being unitarily formed, the first solder mask layer formed on the first wiring layer, and defining a plurality of first openings to expose portions of the first wiring layers, the portions of the first wiring layers exposed at the first openings serving as first contact pads, the chip mounted on the first solder mask layer and electrically connected to the first contact pads.

13. The chip package structure of claim 12, wherein the chip comprises a plurality of electrodes and a plurality of bonding wires correspondingly connected to the electrodes, terminal portions of the bonding wires connected to the first contact pads.

14. The chip package structure of claim 13, further comprising a molding compound layer completely covering the bonding wires, the chip, exposed portions of the first solder mask layer and the first contact pads.

15. The chip package structure of claim 12, further comprising a surface plating layer formed on each of the first contact pads.
